(19) United States
(12) Patent Application Publication
(10) Pub. No.: US 2021/0296275 A1
(43) Pub. Date: Sep. 23, 2021

(54) SEMICONDUCTOR MEMORY DEVICE AND METHOD OF MANUFACTURING THEREOF

(71) Applicant: Kioxia Corporation, Tokyo (JP)

(72) Inventor: Masaki TSUJI, Yokkaichi (JP)

(73) Assignee: Kioxia Corporation, Tokyo (JP)

(21) Appl. No.: 17/017,464

(22) Filed: Sep. 10, 2020

(30) Foreign Application Priority Data
Mar. 19, 2020 (JP) 2020-049933

(51) Int. Cl. H01L 23/00; H01L 25/18; H01L 27/11556; H01L 27/11582; H01L 21/02

(52) U.S. Cl. CPC H01L 24/20; H01L 25/18; H01L 27/11556; H01L 2924/1431; H01L 21/02433; H01L 24/82; H01L 2924/1438; H01L 27/11582

(57) ABSTRACT

A semiconductor memory device according to the present embodiment includes a substrate including a silicon single crystal, a control circuit including a transistor having a channel direction different from [010] direction and [100] direction of the substrate, a circuit wiring layer electrically connected to the control circuit, a first connecting terminal connected to the circuit wiring layer, a plurality of memory cells arranged three-dimensionally, a memory wiring layer electrically connected to the memory cells; and a second connecting terminal connected to the memory wiring layer and the first connecting terminal.

### CROSS REFERENCES TO RELATED APPLICATIONS

This application is based upon and claims the benefit of priority from the prior Japanese Patent Application 2020-049933, filed on Mar. 19, 2020, the entire contents of which are incorporated herein by reference.

### FIELD

Embodiments described herein relate generally to a semiconductor memory device and a manufacturing method for a semiconductor memory device.

### BACKGROUND

A NAND flash memory is known as one type of semiconductor memory device. The NAND flash memory includes a memory cell array and its control circuit. As a method of manufacturing the semiconductor memory device, a memory cell array chip and a control circuit chip formed on the individual semiconductor substrates can be bonded later. It is known that this method can suppress the effect of the temperature of the manufacturing process when forming the memory cell array on the control circuit chip, thereby improving the manufacturing yield of the semiconductor memory device.

### BRIEF DESCRIPTION OF THE DRAWINGS

FIG. 1 is a cross-sectional view of a semiconductor memory device according to the embodiment;

FIG. 2 is a diagram showing a memory cell array wafer according to the embodiment;

FIG. 3 is a diagram showing a control circuit wafer according to the embodiment;

FIG. 4 is a diagram showing the orientation of the memory cell array wafer and a control circuit wafer according to the embodiment; and

FIG. 5 is a diagram showing a method of bonding a memory cell array wafer and a control circuit wafer according to the embodiment.

### DETAILED DESCRIPTION

A semiconductor memory device according to the present embodiment includes a substrate including a silicon single crystal, a control circuit including a transistor having a channel direction different from [010] direction and [100] direction of the substrate, a circuit wiring layer electrically connected to the control circuit, a first connecting terminal connected to the circuit wiring layer, a plurality of memory cells arranged three-dimensionally, a memory wiring layer electrically connected to the memory cells; and a second connecting terminal connected to the memory wiring layer and the first connecting terminal.

Hereinafter, a semiconductor memory device according to the present embodiment will be described in detail by referring to the drawings. In the following description, constituent elements having substantially the same functions and configurations are denoted by the same reference numerals, and duplicate description will be given only when necessary. Each of the embodiments described below exemplifies a device and a method for embodying the technical idea of this embodiment, and the technical idea of the embodiment does not specify the material, shape, structure, arrangement, and the like of the component parts as follows. Various modifications can be made to the technical idea of the embodiment in the claims.

In order to make the description clearer, the drawings may be schematically represented with respect to widths, thicknesses, shapes, and the like of the respective portions in comparison with actual embodiments, but the drawings are only examples and are not intended to limit the interpretation of the present invention. In this specification and each drawing, elements having the same functions as those described with reference to the preceding drawings are denoted by the same reference numerals, and a repetitive description thereof may be omitted.

When the crystal orientation is described in this specification, all crystallographically equivalent directions are included. For example, the (001) plane is equivalent to the (100), (010), (−100), (0-10), and (00-1) planes. The negative Miller index is represented as “−1”.

### [Semiconductor Memory Device]

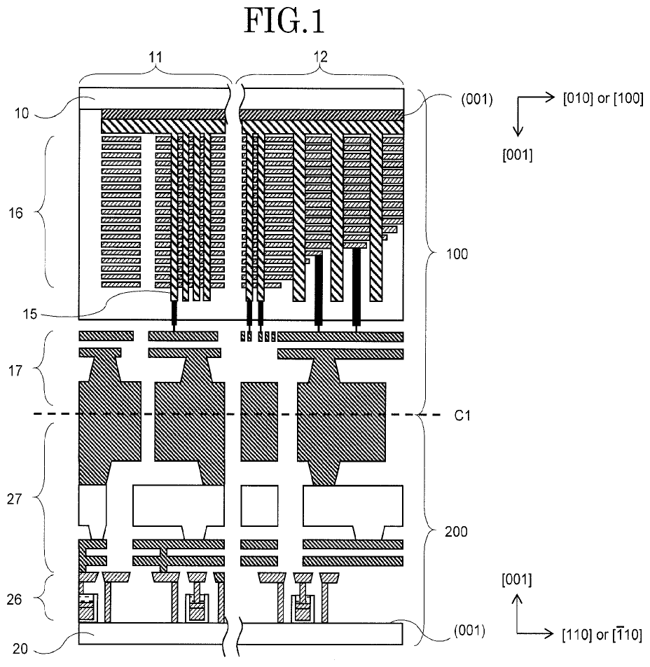

A semiconductor memory device 1 according to the embodiment will be described with reference to FIG. 1. FIG. 1 is a cross-sectional view showing the semiconductor memory device 1. The semiconductor memory device 1 includes a memory cell array chip 100 and a control circuit (CMOS circuit) chip 200.

### [Structure of the Memory Cell Array]

As shown in FIG. 1, the memory cell array chip 100 includes a substrate 10, a plurality of electrode layers 16, a plurality of semiconductor pillars 15, and a memory wiring layer 17. The plurality of electrode layers 16 is stacked on the substrate 10 via one of insulating layers. Another some of the insulating layers are interposed between the electrode layers 16. Each of the semiconductor pillars 15 are arranged in a direction perpendicular to the substrate 10 so as to path through the plurality of stacked electrode layers 16. The semiconductor pillars 15 are combined with the plurality of electrode layers 16 via insulating layers to function as a plurality of transistors including a memory cells. That is, in a memory cell array region 11, the pluralities of transistors including memory cells are arranged three-dimensionally. The semiconductor pillar 15 is electrically connected to the source line at one end (substrate 10 side) and electrically connected to the memory wiring layer 17 at the other end (opposite to the substrate 10 side). Connecting terminals for connecting to the control circuit chip 200 are arranged on the connection surface Cl of the memory wiring layer 17 on the side opposite to the substrate 10.

On the substrate 10, a lead-out region 12 (upper right portion in FIG. 1) is arranged next to the memory cell array region 11. In the lead-out region 12 terminal portions of the plurality of electrode layers 16 are lead out in a stepwise manner, respectively. Each terminal is connected to a vertical wiring through a contact hole provided in the insulating film. These vertical wirings are electrically connected to the memory wiring layer 17, and are connected to the control circuit chip 200 via the connecting terminals.

The substrate 10 may include a single crystal silicon. In this case, the surface of the substrate 10 on which the plurality of memory cells is arranged may be a (001) plane. Note that in this specification, the (001) plane also includes a plane that is shifted by ±10° from the (001) plane. The plurality of electrode layers 16 may be stacked in the [001] direction and the semiconductor pillar 15 may extend in the [001] direction. Thus, the semiconductor pillar 15 may form a plurality of transistors including memory cells connected in series in the [001] direction. The plurality of electrode layers 16 extend in the [010] or [100] direction, and the semiconductor pillars 15 may be arranged in a matrix in the [010] and [100] directions. Accordingly, the pluralities of memory cells may be arranged three-dimensionally in the [001], [010], and [100] directions. The lead-out region 12 may be arranged in the [100] direction and/or the [−100] direction of the memory cell array region 11. With such configuration, deformation of the memory cell array chip 100 can be suppressed when an external force is applied. However, the material of the substrate 10 is not particularly limited and may include glass or resin or the like. The substrate 10 used in the manufacturing process may ultimately be removed from the semiconductor memory device 1.

### [Control Circuit Construction]

As shown in FIG. 1, the control circuit chip 200 includes a substrate 20, a plurality of transistors 26 constituting a control circuit, and a circuit wiring layer 27. The plurality of transistors 26 are formed on the substrate 20, and are electrically connected to the circuit wiring layer 27 on the side opposite to the substrate 20. A connecting terminal for connecting to the memory cell array chip 100 is arranged on the connection surface Cl of the circuit wiring layer 27 on the side opposite to the substrate 20.

The substrate 20 may include the single crystal silicon. In this case, the surface of the substrate 20 on which the plurality of transistors 26 is arranged may be the (001) plane. The channel direction of the plurality of transistors 26 is arranged in a direction different from the [010] direction and the [100] direction of the substrate 20. The channel of the plurality of transistors 26 may be oriented in the [110] and/or [−110] directions of the substrate 20. Here, the direction of the channel indicates the direction of the current flow in the channel. Or, the surface of the substrate 20 on which the plurality of transistors 26 is arranged may be a (111) plane. The substrate 20 may include silicon-germanium, silicon carbide or gallium-arsenide. The substrate 20 may be doped with an impurity. With such configuration, the electron mobility of the channel and driving current of the transistor 26 of the control circuit chip 200 can be increased, thereby transistor performance can be improved.

### [Method of Manufacturing the Semiconductor Memory Device]

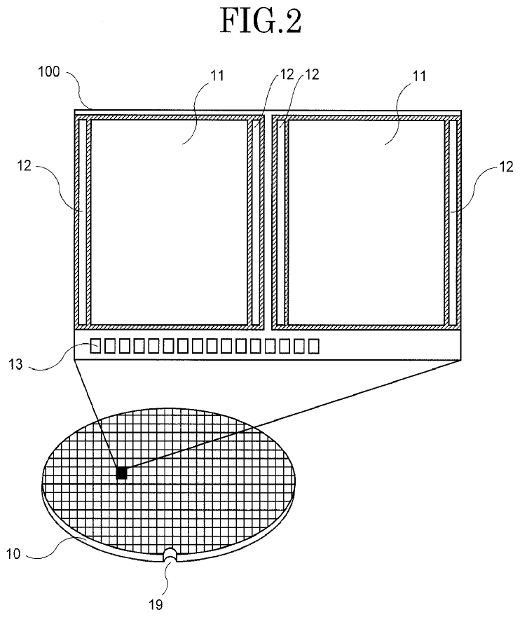

The method of manufacturing the semiconductor memory device according to the present embodiment will be described with reference to FIGS. 2 to 5.

### [Method of Manufacturing a Memory Cell Array Wafer]

FIG. 2 is a diagram showing a basic configuration of a memory cell array wafer. As shown in FIG. 2, the memory cell array wafer includes the plurality of memory cell array chips 100 on the substrate 10. Each of the memory cell array chips 100 includes the memory cell array region 11, the lead-out region 12, and a connecting terminal 13. In the memory cell array region 11, the pluralities of transistors including memory cells are formed three-dimensionally. In the lead-out region 12, the terminal portion is leading out from the plurality of electrode layers 16 constituting the transistors in a stepwise manner. Each of the terminal portions is connected to a wiring formed in the vertical direction through a contact hole provided in the insulating film. These vertical wirings are electrically connected to the memory wiring layer 17 which is formed on the side opposite to the substrate 10. The connecting terminal 13 for connecting to the control circuit chip 200 is formed on the side of the memory wiring layer 17 opposite to the substrate 10.

The substrate 10 of the memory cell array wafer may include the single crystal silicon. In this case, the surface of the substrate 10 on which the plurality of memory cell array chips 100 are formed may be a (001) plane. The plurality of memory cell array chips 100 may be formed in a matrix with a notch 19 of the substrate 10 facing forward. Here, the notch 19 is arranged at the end of the substrate 10 in the [0-10] direction (this is 0°). Therefore, the plurality of memory cell array chips 100 may be formed side by side in the [010] direction and the [100] direction. Since the plurality of memory cell array chips 100 are formed side by side in the [100] direction and the [010] direction, the memory cells of the plurality of memory cell array chips 100 are formed three-dimensionally in the [001], [010], and [100] directions. The memory cell array wafer is formed by aligning a plurality of memory cell array chips 100 in the [100] direction and the [010] direction, so that bending of the memory cell array wafer can be suppressed as compared with the case where the memory cell array wafers are formed by aligning a plurality of memory cell array chips 100 side by side in the [110] direction and the [−101] direction. However, the material of the substrate 10 is not particularly limited, and may include glass or resin or the like.

For example, in the case where the direction of the substrate 10 of the memory cell array wafer is 0° and the case where the direction of the substrate 10 of the memory cell array wafer is 45°, the amount of deformation during the manufacturing process of the memory cell array wafer is shown in Table 1. Here, the memory cell array wafer was formed using the (001) planar silicon substrate having a diameter of 300 mm as the substrate 10. The amount of deformation of the end portion of the memory cell array wafer in the [001] direction is shown in Table 1, where the center of the substrate 10 is set to 0.

TABLE 1

| The direction of the substrate | The amount of deformation |
|---|---|
| 0° | from 100 μm to 200 μm |
| 45° | from 200 μm to 300 μm |

As shown in Table 1, by forming a plurality of memory cell array chips 100 in the substrate 10 of 0°, deformation of the memory cell array wafer can be suppressed.

### [Methods of Manufacturing a Control Circuit Wafer]

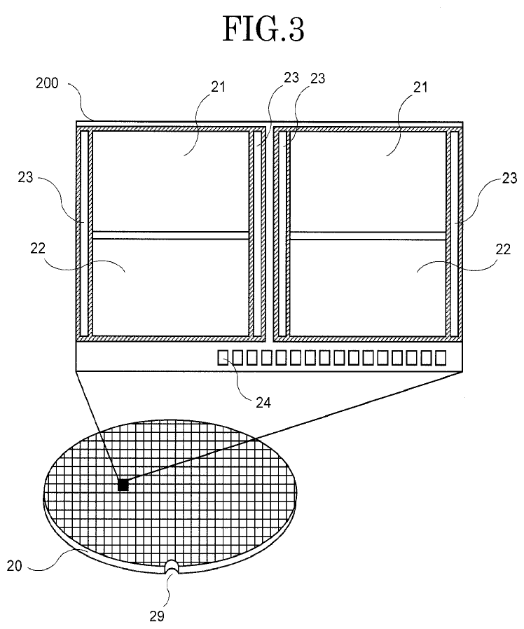

FIG. 3 is a diagram showing a basic configuration of a control circuit wafer. As shown in FIG. 3, the control circuit wafer includes the plurality of control circuit chips 200 on the substrate 20. Each of the control circuit chips 200 includes a sense amplifier region 21, peripheral circuitry region 22, driving circuit region 23, and a connecting terminal 24. In the sense amplifier region 21, the sense amplifier circuit is formed. In the peripheral circuit region 22, for example, control circuits such as controller, input/output circuit, voltage generating circuit, address register, bunch decoder and row decoder, data cache, column decoder and the like are formed. In the driving circuit region 23, for example, various driving circuit of the row system is formed. In the transistor 26 constituting these circuits, the channel is formed in a direction different from the [010] direction and the [100] direction of the substrate 20. Each circuit is electrically connected to the circuit wiring layer 27 which is formed on the side opposite to the substrate 20. The connecting terminals 24 for connecting to the memory cell array chip 100 is formed on the connection surface Cl of the circuit wiring layer 27 on the side opposite to the substrate 20.

The substrate 20 of the control circuit wafer may include the single crystal silicon. In this case, the surface of the substrate 20 on which the plurality of control circuit chips 200 are formed may be the (001) plane. The plurality of control circuit tips 200 may be formed in a matrix with a notch 29 of the substrate 20 facing forward. Here, the notch 29 is arranged at the end of the substrate 20 in the [1-10] direction (this is 45°). Therefore, the plurality of control circuit tips 200 may be formed side by side in the [110] direction and [−110] direction. The plurality of control circuit chips 200 are formed side by side in the [110] direction and the [−110] direction, so that the transistors 26 of the plurality of control circuit chips 200 are formed in the [110] direction and/or the [−110] direction. However, the surface of the substrate 20 on which the plurality of control circuit chips 200 are formed may be a (111) plane.

The substrate 20 may include silicon-germanium, silicon carbide, or gallium-arsenide. The substrate 20 may be doped with impurities. By forming the control circuit wafer in this manner, the electron mobility of the channel and driving current of the transistor 26 of the control circuit chip 200 of the control circuit wafer can be increased, thereby transistor performance can be improved.

### [Bonding the Memory Cell Array Wafer and the Control Circuit Wafer]

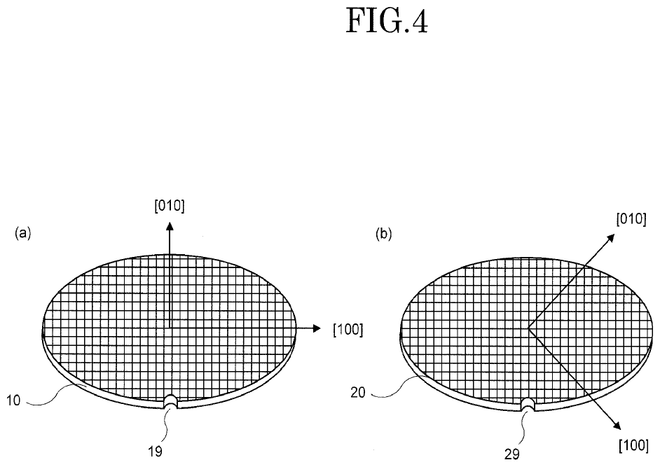

FIG. 4 is a diagram showing the crystallographic orientation of substrate of the memory cell array wafer and the control circuit wafer. As shown in FIG. 4, the crystal orientation of the substrate 10 of the memory cell array wafer is different from the crystal orientation of the substrate 20 of the control circuit wafer. In FIG. 4, the memory cell array chip 100 or the control circuit chip 200 is formed on the (001) plane of both the substrate 10 of the memory cell array wafer and the substrate 20 of control circuit wafer. On the other hand, the direction of the substrate 10 of the memory cell array wafer is 0°, whereas the direction of the substrate 20 of the control circuit wafer is 45°. Accordingly, a plurality of memory cell array chips 100 of the memory cell array wafer are formed in the [010] direction and the [100] direction, and the plurality of control circuit chips 200 of the control circuit wafer are formed in the [110] direction and the [−110] direction. However, the present invention is not limited thereto, and the substrate 10 of the memory cell array wafer and the substrate 20 of the control circuit wafer may have different compositions as described above.

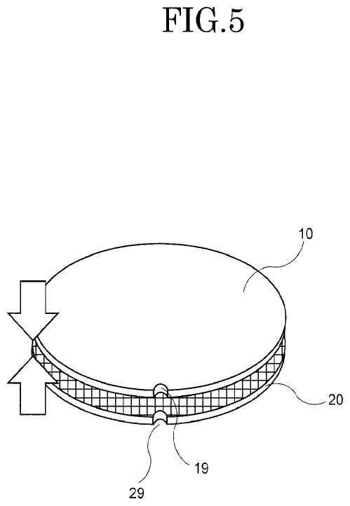

FIG. 5 is a diagram showing a method of bonding a memory cell array wafer and the control circuit wafer. As shown in FIG. 5, the memory cell array wafer and the control circuit wafer are bonded so that a plurality of memory cell array chips 100 and the plurality of control circuit chips 200 face each other. The bonding method is not particularly limited. For example, the top surface of the memory cell array wafer and the control circuit wafer may be contacted and bonded at temperatures of 300° C. or higher and 400° C. or lower under the predetermined pressures. By bonding a plurality of memory cell array chips 100 and the plurality of control circuit chips 200 so as to face each other, the connecting terminals 13 on the memory cell array chip 100 are connected to the connecting terminals 24 on the control circuit chip 200. On the other hand, the direction of the substrate 10 of the memory cell array wafer and the direction of the substrate 20 of the control circuit wafer are bonded by being shifted by 45° in the plane direction.

After bonding the memory cell array wafer and the control circuit wafer, it may be divided into the individual semiconductor memory device 1. The substrate 10 may be removed before the semiconductor memory device 1 is divided.

The manufacturing method of the semiconductor memory device 1 according to this embodiment can improve the productivity and performance of the semiconductor memory device 1 by the fact that the substrate 10 of the memory cell array wafer and the substrate 20 of the control circuit wafer have different crystal orientations or compositions.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate including a silicon single crystal;
a control circuit including a transistor having a channel direction different from [010] direction and [100] direction of the substrate;
a circuit wiring layer electrically connected to the control circuit;
a first connecting terminal connected to the circuit wiring layer;
a plurality of memory cells arranged three-dimensionally;
a memory wiring layer electrically connected to the memory cells; and
a second connecting terminal connected to the memory wiring layer and the first connecting terminal.

2. A semiconductor memory device comprising:
a first substrate including a first surface;
a control circuit arranged on the first surface;
a circuit wiring layer electrically connected to the control circuit;
a first connecting terminal connected to the circuit wiring layer;
a second substrate having a crystal orientation or composition different from that of the first substrate and having a second surface;
a plurality of memory cells arranged three-dimensionally above the second surface;
a memory wiring layer electrically connected to the memory cells; and
a second connecting terminal connected to the memory wiring layer and the first connecting terminal.

3. The semiconductor memory device according to claim 2, wherein the first substrate and the second substrate have different crystal orientations.

4. The semiconductor memory device according to claim 3, wherein
the first surface and the second surface are (001) plane of the silicon-based single crystal substrate;
the control circuit includes a transistor having a channel arranged in a different direction from [010] direction and [100] direction; and
the memory cells are arranged three-dimensionally in [001] direction, [010] direction, and [100] direction.

5. The semiconductor memory device according to claim 3, wherein
the second surface is a (111) plane of the silicon-based single crystal substrate;
the first surface is a (001) plane of the silicon-based single crystal substrate; and
the memory cells are arranged three-dimensionally in [010] direction, [100] direction, and [001] direction.

6. The semiconductor memory device according to claim 2, wherein the first substrate and the second substrate have different compositions.

7. The semiconductor memory device according to claim 6, wherein the first substrate and the second substrate include silicon and the second substrate further includes germanium.

8. A method for manufacturing a semiconductor memory device comprising:
forming a control circuit wafer including
a first substrate having a first surface,
a control circuit arranged on the first surface,
a circuit wiring layer electrically connected to the control circuit,
a first connecting terminal connected to the circuit wiring layer;
forming a memory cell array wafer including
a second substrate having a crystal orientation or composition different from that of the first substrate, the second substrate having a second surface,
a plurality of memory cells arranged three-dimensionally above the second surface,
a memory wiring layer electrically connected to the memory cells, and
a second connecting terminal connected to the memory wiring layer; and
connecting the first connecting terminal and the second connecting terminal by bonding the control circuit wafer and the memory cell array wafer.

9. The method for manufacturing the semiconductor memory device according to claim 8, wherein the first substrate and the second substrate have different crystal orientations.

10. The method for manufacturing the semiconductor memory device according to claim 9, wherein
the first surface and the second surface are (001) plane;
forming the control circuit wafer includes forming a transistor having a channel direction different from [010] direction and [100] direction; and
forming the memory cell array wafer includes forming the memory cells in [010] direction, [100] direction, and [001] direction.

11. The method for manufacturing the semiconductor memory device according to claim 9, wherein
the control circuit wafer and the memory cell array wafer include single crystal silicon.

12. The method for manufacturing the semiconductor memory device according to claim 11, wherein
the second surface is a (111) plane;
the first surface is a (001) plane;
forming the memory cell array wafer includes forming the memory cells in [010] direction, [100] direction, and [001] direction.

13. The method for manufacturing the semiconductor memory device according to claim 8, wherein the first substrate and the second substrate have different compositions.

14. The method for manufacturing the semiconductor memory device according to claim 13, wherein the first substrate and the second substrate include silicon and the second substrate further includes germanium.
